(19) United States
(12) Patent Application Publication
(10) Pub. No.: US 2025/0274130 A1
(43) Pub. Date: Aug. 28, 2025

(54) ADAPTIVE ANALOG-TO-DIGITAL CONTROLLER

(71) Applicant: TEXAS INSTRUMENTS INCORPORATED, Dallas, TX (US)

(72) Inventors: Anand Kumar G, Bangalore (IN); Veeramanikandan Raju, Bangalore (IN)

(21) Appl. No.: 18/586,192

(22) Filed: Feb. 23, 2024

(51) Int. Cl. H03L 7/091; H03L 7/099

(52) U.S. Cl. CPC H03L 7/091; H03L 7/0992

(57) ABSTRACT

Various embodiments disclosed herein relate to adaptive clock signal management, and more specifically, to transitioning between clock frequencies to convert analog signals to digital signals at dynamic sampling rates. In an example embodiment, a device including an analog-to-digital converter (ADC) and a control circuit coupled to the ADC is provided. The ADC is configured to receive a first analog signal, receive a first clock signal, and generate a first set of digital values corresponding to the first analog signal based on the first clock signal. The control circuit is configured to determine that a change in the first set of digital values satisfies a first threshold value and increase the first clock signal from a first frequency to a second frequency in response to determining that the change in the first set of digital values satisfies the first threshold value.

### TECHNICAL FIELD

This relates generally to digital signal processing, and more particularly, to analog-to-digital signal converters and operation thereof.

### BACKGROUND

In electronic systems, digital signal processing components may be included to sample and convert analog signals to digital signals for use by various components of the electronic systems. To operate the digital signal processing components, an electronic system may supply the components with a supply power and with a clock signal. In various examples, such as digital signal processing components include an analog-to-digital converter (ADC). ADCs may operate at various speeds, referred to as sampling rates, to convert the analog signals to digital signals based on the frequency of the supplied clock signal.

In existing systems including ADCs to convert analog inputs to digital outputs, the systems may produce a clock signal either to optimize power consumption of the system or to increase the number of digital outputs produced by the ADC. In a first example, a low-power system may operate an ADC at a nominal sampling rate using a clock signal having a frequency that is used and synchronized among various elements of the system. In such systems, the ADC might not be operated at sampling rates higher than the nominal sampling rate due to power constraints. In a second example, a system may operate an ADC at a high sampling rate, relative to the nominal sampling rate, without operating the ADC at the nominal sampling rate. While such solutions produce higher numbers of digital outputs based on the increased sampling rate, the ADC consumes increased amounts of power, which may limit available power for other elements of the system. Additionally, increased numbers of digital outputs may produce a high load on a bus interconnect of the system.

### SUMMARY

Disclosed herein are improvements to digital signal processing, and more particularly, to dynamically configuring a sampling rate of an analog-to-digital converter (ADC) to perform sampling and conversion operations at various speeds during operation thereof. An example embodiment includes an ADC and a control circuit coupled to the ADC. The ADC is configured to receive a first analog signal, receive a first clock signal, and generate a first set of digital values corresponding to the first analog signal based on the first clock signal. The control circuit is configured to determine that a change in the first set of digital values satisfies a first threshold value and increase the first clock signal from a first frequency to a second frequency in response to determining that the change in the first set of digital values satisfies the first threshold value.

This Summary is provided to introduce a selection of concepts in a simplified form that are further described below in the Detailed Description. It may be understood that this Summary is not intended to identify key features or essential features of the claimed subject matter, nor is it intended to be used to limit the scope of the claimed subject matter.

### BRIEF DESCRIPTION OF THE DRAWINGS

FIG. 1 illustrates an example system configurable to perform adaptive clock frequency processes in an implementation.

FIG. 2 illustrates a series of steps for dynamically transitioning the frequency of a clock signal during operation of an analog-to-digital converter in an implementation.

FIG. 3 illustrates a sequence diagram for converting analog signals to digital signals using dynamic sampling rates in an implementation.

FIG. 4 illustrates an example system configurable to perform adaptive clock frequency processes in an implementation.

FIG. 5 illustrates an example timing diagram corresponding to dynamically transitioning the frequency of a clock signal during operation of an analog-to-digital converter in an implementation.

FIG. 6 illustrates an example timing diagram corresponding to dynamically transitioning the frequency of a clock signal during operation of an analog-to-digital converter in an implementation.

FIG. 7 illustrates an example system configurable to perform adaptive clock frequency processes in an implementation.

FIG. 8 illustrates an example circuit configurable to perform adaptive clock frequency processes in an implementation.

The drawings are not necessarily drawn to scale. In the drawings, like reference numerals designate corresponding parts throughout the several views. In some embodiments, components or operations may be separated into different blocks or may be combined into a single block.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the invention(s), and do not limit the scope of the invention(s).

The description below illustrates the various specific details to provide an in-depth understanding of several example embodiments according to the description. The embodiments may be obtained without one or more of the specific details, or with other methods, components, materials and the like. In other cases, known structures, materials or operations are not shown or described in detail so as not to obscure the different aspects of the embodiments. References to “an embodiment” in this description indicate that a particular configuration, structure or feature described in relation to the embodiment is included in at least one embodiment. Consequently, phrases such as “in one embodiment” that may appear at different points of the present description do not necessarily refer exactly to the same embodiment. Furthermore, specific formations, structures or features may be combined in any appropriate manner in one or more embodiments.

Embodiments of the present disclosure will be described in specific contexts, such as in tire pressure monitoring systems with respect to sampling increased amounts of data based on inputs from tire pressure monitoring system (TPMS)-related sensors (e.g., an accelerometer sensor). Some embodiments may be used in other applications in which generating increased amounts of data under certain conditions as indicated through triggers may be beneficial, such as for collection of fitness data in wearable devices, for collection of safety or operation metrics in industrial applications, for collection of predictive intelligence in cloud applications and machine learning applications, for collection of sensors across multiple streams in fusion applications employing fusion algorithms, and the like. Other potential systems include the collection of medical data (e.g., patient monitoring), collection of data in edge computing devices or IoT devices, or automotive applications other than tire pressure sensors.

Discussed herein are enhanced components, techniques, and systems related to analog-to-digital signal conversion, and more particularly, to controlling frequencies of clock signals used for analog-to-digital signal conversion based on conditions. As discussed in detail below, the conditions may relate to received analog signals and/or indicated by triggers. In a system, an analog-to-digital converter (ADC) may be included to sample analog input signals and convert the analog input signals to digital output signals for use by downstream components and systems. To operate the ADC, elements of the system provide a clock signal having a frequency to the ADC. The ADC uses the clock signal to perform conversion cycles during which the ADC converts analog input signals to digital output signals. The sampling rate at which the ADC performs such conversion may be based on the frequency of the clock signal provided to the ADC. In existing solutions, the ADC may be operated at either a base, or nominal, frequency during all conversion operations or at an increased frequency during all conversion operations. Problematically, this may lead to lack of digital measurements to identify issues within a system when sampling only at the base rate or to unnecessary power consumption within the system when sampling only at the increased rate. Instead, as discussed herein, a system may include control circuitry, selector circuitry, and clock divider circuitry coupled to an ADC to modify (e.g., increase or decrease) the sampling rate of the ADC on-the-fly based on input signals, or triggers, to the system. Advantageously, such a system can increase the sampling rate of the ADC when a device indicates that a condition has occurred (e.g., a vehicle has begun to move, a temperature, pressure, or other parameter has increased above a threshold, an operating voltage has decreased below a threshold) and can decrease the sampling rate to a base rate after an amount of data has been sampled or after a certain duration, which may not only improve bus efficiency, but also increase power consumption efficiency and decrease overall power consumption. In addition, a system of this disclosure may quickly adapt to changes in the environment without stopping the ADC.

One example embodiment of the disclosed technology includes a device comprising an analog-to-digital converter and a control circuit coupled to the ADC. The ADC is configured to receive a first analog signal, receive a first clock signal, and generate a first set of digital values corresponding to the first analog signal based on the first clock signal. The control circuit is configured to determine that a change in the first set of digital values satisfies a first threshold value and increase the first clock signal from a first frequency to a second frequency in response to determining that the change in the first set of digital values satisfies the first threshold value.

In another example, a method of dynamically changing the frequency of a clock signal is provided. The method includes receiving a first clock signal and receiving a first analog signal. The method further includes generating a first set of digital values corresponding to the first analog signal based on the first clock signal and determining that a change in the first set of digital values satisfies a first threshold value. The method also includes increasing the first clock signal from a first frequency to a second frequency in response to determining that the change in the first set of digital values satisfies the first threshold value.

In yet another embodiment, a system including a sensor, an ADC coupled to the sensor, and a control circuit coupled to the ADC. The ADC is configured to receive a first analog signal, receive a first clock signal, and generate a first set of digital values corresponding to the first analog signal based on the first clock signal. The control circuit is configured to determine that a change in the first set of digital values satisfies a first threshold value and increase the first clock signal from a first frequency to a second frequency in response to determining that the change in the first set of digital values satisfies the first threshold value.

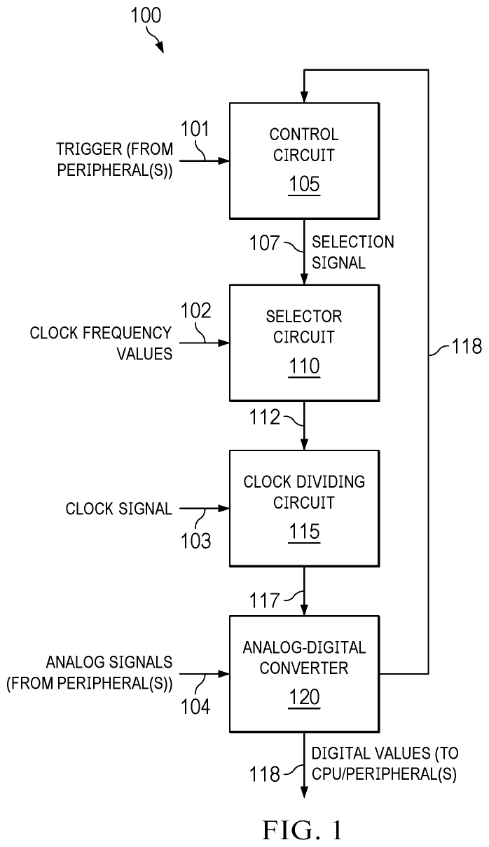

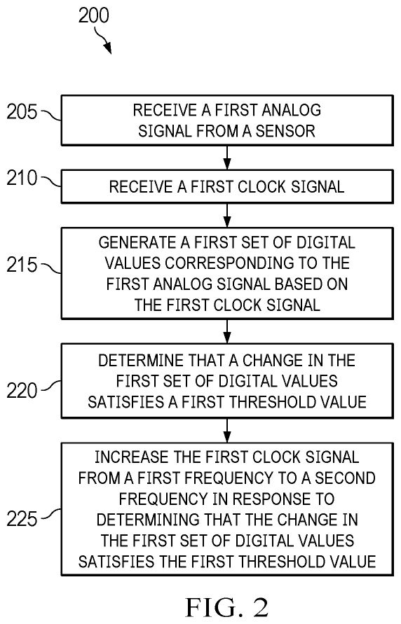

FIG. 1 illustrates an example system 100 configurable to perform adaptive clock frequency processes in an implementation. FIG. 1 shows system 100, which includes control circuit 105, selector circuit 110, clock dividing circuit 115, and analog-to-digital converter (ADC) 120. Elements of system 100 may be configured to perform sampling and conversion operations and clock frequency transitioning techniques during the sampling and conversion operations, such as in operations 200 of FIG. 2.

In various embodiments, system 100 may be representative of a digital signal processing system capable of receiving analog signals 104, converting analog signals 104 at a desired sampling rate, and producing digital values 118 from analog signals 104 based on parameters and inputs, such as trigger 101. Elements of system 100 may include dedicated, fixed-purpose hardware components capable of performing sampling and conversion operations and clock frequency management operations, such as operations 200 of FIG. 2. System 100 may be embodied in circuitry utilized in an embedded system, integrated circuit, field-programmable gate array, and/or system-on-chip (SoC), such as a microcontroller unit (MCU). In an example, system 100 may include fewer, additional, or different elements that produce inputs to elements of system 100 or that receive outputs from system 100 (e.g., a central processing unit (CPU), one or more peripherals, a clock generation circuit).

Control circuit 105 may be representative of one or more devices configured to receive trigger 101 and output selection signal 107 based on trigger 101. Trigger 101 may be a hardware trigger, e.g., generated by a peripheral (e.g., a sensor), or a software trigger, e.g., generated by a system or circuit (e.g., a CPU) based on execution of program instruction(s). In some embodiments, trigger 101 may include a logical low value (e.g., “0”) or a logical high value (e.g., “1”). In some embodiments, trigger 101 may instead, or in addition, include an indication of the peripheral and corresponding analog signals 104 of the peripheral. Based on trigger 101, control circuit 105 can produce selection signal 107 with a value corresponding to the logical value of trigger 101 and/or the indication of the peripheral.

Selector circuit 110 may be representative of one or more devices configured to receive clock frequency values 102 and selection signal 107 and produce a selection value 112 based on selection signal 107. In some embodiments, clock frequency values 102 may include indications of frequency values of clock signals. For example, clock frequency values 102 may include a first indication of a first frequency value of a clock signal and a second indication of a second frequency value of the clock signal. In some embodiments, clock frequency values 102 may include indications of clock division values, such that when a first clock division value is applied to a clock signal, the clock signal may be produced having a frequency corresponding to the first frequency value. In some embodiments, clock frequency values 102 may be stored in a configurable register. Additionally, in some embodiments, ADC 120 may be configured to perform sampling and conversion operations on different analog signals 104 which may require clock signals of different frequencies. Thus, the register may include multiples sets of clock frequency values 102. Each set may correspond to a particular analog signal 104 and may include one or more clock frequency values 102. When receiving selection signal 107 and an indication of a particular analog signal 104, selector circuit 110 may access the register and obtain a corresponding clock frequency value 102 accordingly. Selector circuit 110 may be configured to provide selection value 112 to clock dividing circuit 115. In some examples, selection value 112 is a clock frequency value, a clock division value, or a clock multiplication value.

Clock dividing circuit 115 may be representative of one or more devices configured to receive clock signal 103, receive selection value 112, generate clock signal 117 based on selection value 112, and provide clock signal 117 to ADC 120, such that ADC 120 can perform sampling and conversion operations with a sampling rate based on clock signal 117. In various embodiments, clock signal 103 includes a signal with a base frequency (e.g., a nominal or default frequency). Clock dividing circuit 115 may be configured to apply a value, based on selection value 112, to clock signal 103 to generate clock signal 117. In some embodiments, applying the value to clock signal 103 may entail dividing the base frequency of clock signal 103 by an amount based on selection value 112 such that clock signal 117 has a first frequency distinctive of, or different or separate from, the base frequency. In some embodiments, applying the value to clock signal 103 may entail multiplying the base frequency of clock signal 103 by a value based on selection value 112 such that clock signal 117 has a first frequency different from the first frequency. Regardless, clock dividing circuit 115 may be configured to manipulate the frequency of clock signal 103 to produce clock signal 117, which, when provided to ADC 120, may cause ADC 120 to perform operations with a sampling rate based on clock signal 117. Other methods of altering the frequency of clock signal 103 to produce clock signal 117 may be contemplated.

ADC 120 may be representative of one or more devices capable of performing the sampling and conversion operations on analog signals 104 based on clock signal 117 to produce digital values 118. For example, ADC 120 may include a successive-approximation register (SAR) ADC, a delta-sigma ADC, or a dual-slope ADC, among other types of ADCs. ADC 120 may be coupled to receive one or more analog signals 104 from one or more peripherals and may be configured to convert analog signals 104 at a sampling rate based on clock signal 117. In some embodiments, ADC 120 may be configured to convert analog signals 104 sequentially. For example, ADC 120 may first receive (e.g., sample) and convert an analog signal 104 at one corresponding sampling rate. After the sampling and conversion operations of the analog signal 104 complete, ADC 120 may receive and convert a next analog signal 104 at another corresponding sampling rate. ADC 120 may repeat the process until the end of sampling and conversion operations of all analog signals 104. In other words, ADC 102 may include a common set of hardware or circuits shared by different analog signals 104, where analog signals 104 may be received and converted one by one. In some embodiments, ADC 102 may include multiple sets of hardware or circuits, each allocated to a specific analog signal 104. ADC 102 may be configured to utilize the hardware or circuits to perform sampling and conversion operations on multiple analog signals 104 in parallel. In some embodiments, ADC 120 may instead, or in addition, be configured to receive analog signals 104 via one or more external pins (e.g., a microcontroller pin, a device pin). As ADC 120 converts the analog signals 104 to sets of digital values 118, ADC 120 can provide the digital values 118 downstream to other systems, subsystems, or devices (e.g., a CPU, a direct memory access (DMA) controller, a buffer, one or more peripherals) and to control circuit 105.

In some embodiments, in addition to receiving trigger 101, control circuit 105 may be configured to adjust the frequency of clock signal 117 based on analog signals 104. For example, in some embodiments, in response to receiving digital values 118 (that are generated based on analog-to-digital conversion of analog signals 104), control circuit 105 may be configured to determine that a change in a first set of digital values 118 (corresponding to a first analog signal 104) satisfies a first threshold value. More specifically, control circuit 105 may determine the change in the first set of digital values 118 based on a difference between two digital values (e.g., consecutive digital values) of the first set of digital values 118 produced by ADC 120. The first threshold value may correspond to a delta value between the two digital values. Satisfying the first threshold value may refer to when the change exceeds a threshold and/or when an absolute value of the change exceeds a threshold.

Control circuit 105 may include a comparator circuit to determine that the change in the digital values 118 satisfies the first threshold value. In particular, the comparator circuit may be configured to compare the difference between the two digital values and the first threshold value to determine that the difference satisfies the first threshold value. Based on such a determination, control circuit 105, or the comparator circuit thereof, may be configured to generate a value for selection signal 107 and provide selection signal 107 to selector circuit 110, such that selector circuit 110 outputs selection value 112 having a value that causes clock dividing circuit 115 to generate clock signal 117 with a second frequency that is distinctive of the first frequency.

In various embodiments, control circuit 105 may also be configured to monitor and/or control the lengths of duration that clock signal 117 has a particular frequency. To do so, control circuit 105 may include a counter circuit that is configured to generate a counter value representing the length of a duration in which clock signal 117 has a frequency. Following an example in which clock signal 117 includes a signal with a first frequency, the counter circuit may be configured to compare the counter value to a duration value to determine whether the length of duration in which clock signal 117 has the first frequency exceeds a duration value. Based on determining that the length of duration exceeds the duration value, control circuit 105, or the comparator circuit thereof, may be configured to generate another value for selection signal 107 and provide selection signal 107 to selector circuit 110, such that selector circuit 110 outputs selection value 112 having a value that causes clock dividing circuit 115 to generate clock signal 117 with another frequency that is distinctive of the first frequency.

In some embodiments, the counter circuit may be configured to initiate the counter value in response to receiving the signal from the comparator circuit that indicates that the change in the first set of digital values satisfies the first threshold value. In other words, following the previous example, the counter circuit may be configured to initiate the counter value after ADC 120 produces the first set of digital values using clock signal 117 at one frequency and prior to ADC 120 producing a second set of digital values using clock signal 117 at a different frequency, which may be changed based on the change in the first set of digital values satisfying the threshold value. In some embodiments, the counter circuit may instead, or in addition, be configured to initiate the counter value in response to receiving a start signal from another system or circuit (e.g., the CPU, a peripheral).

It follows that ADC 120 may be configured to perform sampling and conversion operations at varied sampling rates based on clock signal 117. The sampling rate, or more particularly, the frequency of clock signal 117, may be determined and changed based on one or more factors like the value of trigger 101, the value of the counter value, and/or the value of a change between values of digital values 118. ADC 120 may be configured to operate in a high-sampling mode when the frequency of clock signal 117 is higher than a base clock frequency, in an oversampling mode when the frequency of clock signal 117 meets or exceeds the Nyquist rate, in an undersampling or decreased sampling mode when the frequency of clock signal 117 is below the base clock frequency, or at a base sampling mode when the frequency of clock signal 117 is at the base frequency, such as at the frequency of clock signal 103. For example, in some embodiments, clock signal 117 may be at a base frequency in the base sampling mode, which may meet or exceed the Nyquist rate (if applicable). Thus, the term “oversampling” may refer to a sampling rate that is higher than a base rate, rather than a sampling rate that is higher than the Nyquist rate. In the high-sampling mode, the frequency of clock signal 117 may increase by N times to N times the base frequency (where N is a number larger than 1). ADC 120 may operate in the high-sampling mode for a duration of period, and at the end of the duration (e.g., determined by a counter circuit as described above) the frequency of clock signal 117 may reduce back to the base frequency.

For each iteration of sampling and conversion via ADC 120, control circuit 105 may be configured to compare changes in values of digital values 118 against the threshold value to determine whether to increase or decrease the frequency of clock signal 117. For each iteration of sampling and conversion via ADC 120 in which clock signal 117 includes a signal with a frequency higher than the base frequency, control circuit 105 may be configured to initiate the counter value via the counter circuit to determine whether to decrease the frequency of clock signal 117.

FIG. 2 illustrates a series of steps for dynamically transitioning the frequency of a clock signal during operation of an analog-to-digital converter in an implementation. FIG. 2 shows operations 200, which reference elements of FIG. 1.

In operation 205, ADC 120 is configured to receive a first analog signal of analog signals 104 from a sensor. ADC 120 may be representative of one or more devices capable of performing sampling and conversion operations on analog signals 104 at a sampling rate to produce digital values 118. For example, ADC 120 may include a successive-approximation register (SAR) ADC, among other types of ADCs. Examples of the sensor may include a tire pressure monitoring sensor, an accelerometer sensor, a vibration sensor, a temperature sensor, a current sensor, a voltage sensor, light sensor, sound sensor, or the like. During operation, the sensor may collect analog data and provide the data as analog signals 104 to ADC 120.

In operation 210, ADC 120 is configured to receive a first clock signal 117. ADC 120 may be coupled to clock dividing circuit 115 to receive clock signal 117. Clock signal 117 may include a signal having a first frequency. ADC 120 can perform the sampling and conversion operations at the sampling rate based on the first frequency of clock signal 117. For example, ADC 120 may be configured to operate with a high sampling rate in a high-sampling mode when the first frequency of clock signal 117 is higher than a base clock frequency. ADC 120 may be configured to operate with a low sampling rate in a low-sampling or under-sampling mode when the first frequency of clock signal 117 is below the base clock frequency. ADC 120 may be configured to operate with a base sampling rate in a base sampling mode when the first frequency of clock signal 117 is at the base frequency.

In operation 215, ADC 120 generates a first set of digital values 118 corresponding to the first analog signal based on clock signal 117. As ADC 120 converts the analog signal to the first set of digital values 118, ADC 120 can provide the digital values 118 downstream to other systems, subsystems, or devices (e.g., a CPU, a direct memory access (DMA) controller, one or more peripherals) and to control circuit 105.

In operation 220, in response to receiving digital values 118, control circuit 105 may be configured to determine that a change in a first set of digital values 118 satisfies a first threshold value. More specifically, control circuit 105 may determine the change in the first set of digital values 118 based on a difference between two digital values (e.g., between two or more consecutive digital values) of the first set of digital values 118 produced by ADC 120. The first threshold value may correspond to a delta value between the two digital values. Satisfying the first threshold value may refer to when the change exceeds a threshold and/or when an absolute value of the change exceeds a threshold.

Control circuit 105 may include a comparator circuit to determine that the change in the digital values 118 satisfies the first threshold value. In particular, the comparator circuit may be configured to compare the difference between the two digital values and the first threshold value to determine that the difference satisfies the first threshold value. In operation 225, based on such a determination, control circuit 105, or the comparator circuit thereof, may be configured to generate a value for selection signal 107 and provide selection signal 107 to selector circuit 110, such that selector circuit 110 outputs selection value 112 having a value that causes clock dividing circuit 115 to increase the frequency of clock signal 117 from a first frequency to a second frequency that is distinctive of the first frequency. As described above, in some embodiments, control circuit 105 may receive external (hardware and/or software) trigger 101 and in response generate a value for selection signal 107 to cause an increase of the frequency of clock signal 117. In other words, the frequency of clock signal 117 may be adjusted based on a variety of conditions, e.g., whether a change in digital values 118 satisfies a first threshold value, whether trigger 101 is received, and/or whether ADC 120 has operated at an increased frequency of clock signal 117 for a specified duration of period.

Selector circuit 110 may be representative of one or more devices configured to receive clock frequency values 102 and selection signal 107 and produce a selection value 112 based on selection signal 107. In some embodiments, clock frequency values 102 may include indications of frequency values of clock signals. For example, clock frequency values 102 may include a first indication of a first frequency value of a clock signal and a second indication of a second frequency value of the clock signal. In some embodiments, clock frequency values 102 may include indications of clock division values, such that when a first clock division value is applied to a clock signal, the clock signal may be produced having a frequency corresponding to the first frequency value. Following the example above, in response to receiving selection signal 107 that indicates the second frequency, selector circuit 110 may be configured to produce selection value 112 with an indication thereof and provide selection value 112 to clock dividing circuit 115.

Clock dividing circuit 115 may be representative of one or more devices configured to generate clock signal 117 at a given frequency based on selection value 112, and provide clock signal 117 to ADC 120, such that ADC 120 can perform the sampling and conversion operations with a sampling rate based on clock signal 117. Continuing with the above example, clock dividing circuit 115 may be configured to apply a value based on selection value 112 to clock signal 117 to increase the first frequency of clock signal 117 to the second frequency. Then, clock dividing circuit 115 can provide clock signal 117 at the second frequency to ADC 120 for further sampling and conversion of analog signals 104.

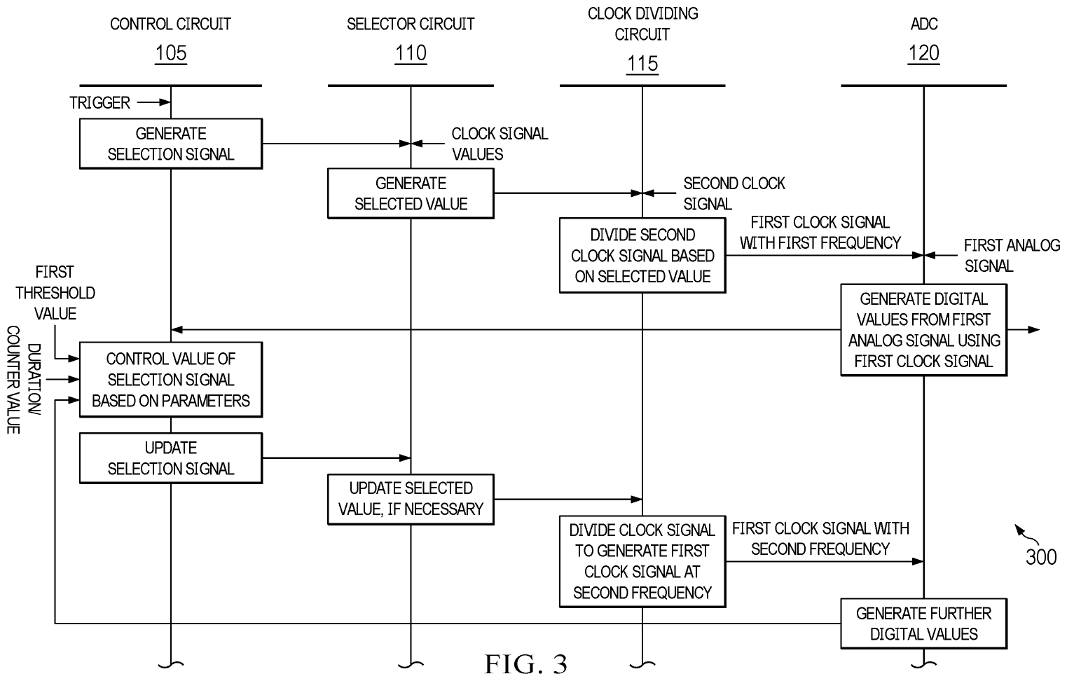

FIG. 3 illustrates a sequence diagram for converting analog signals to digital signals using dynamic sampling rates in an implementation. FIG. 3 shows sequence diagram 300, which references elements of FIG. 1, such as control circuit 105, selector circuit 110, clock divider circuit 115, and ADC 120.

Control circuit 105 may be representative of one or more devices configured to receive trigger 101 and output selection signal 107 based on trigger 101. Trigger 101 may be a hardware trigger, e.g., generated by a peripheral (e.g., a sensor), or a software trigger, e.g., generated by a system or circuit (e.g., a CPU) based on execution of program instruction(s). In some embodiments, trigger 101 may include a logical low value (e.g., “0”) or a logical high value (e.g., “1”). In some embodiments, trigger 101 may instead, or in addition, include an indication of the peripheral and corresponding analog signals 104 of the peripheral. Based on trigger 101, control circuit 105 can produce selection signal 107 with a value corresponding to the logical value of trigger 101 and/or the indication of the peripheral.

Selector circuit 110 may be representative of one or more devices configured to receive clock signal values (e.g., clock frequency values 102) and selection signal 107 and produce a selection value 112 (e.g., a clock frequency value, a clock division value, a clock multiplication value) based on selection signal 107. In some embodiments, clock frequency values 102 may include indications of frequency values of clock signals. For example, clock frequency values 102 may include a first indication of a first frequency value of a clock signal and a second indication of a second frequency value of the clock signal. In some embodiments, clock frequency values 102 may include indications of clock division values, such that when a first clock division value is applied to a clock signal, the clock signal may be produced having a frequency corresponding to the first frequency value. Selector circuit 110 may be configured to provide selection value 112 to clock dividing circuit 115.

Clock dividing circuit 115 may be representative of one or more devices configured to receive a clock signal (e.g., clock signal 103), receive selection value 112 from selector circuit 110, generate another clock signal (e.g., clock signal 117) (or modify the received clock signal) based on selection value 112, and provide a clock signal with a first frequency to ADC 120, such that ADC 120 can perform sampling and conversion operations with a sampling rate based on the first frequency of the clock signal. In various embodiments, the received clock signal, clock signal 103, includes a signal having a base frequency (e.g., a nominal or default frequency). Clock dividing circuit 115 may be configured to apply a value, based on selection value 112, to clock signal 103 to generate clock signal 117 having a first frequency. In some embodiments, applying the value to clock signal 103 may entail dividing the base frequency of clock signal 103 by an amount based on selection value 112 such that clock signal 117 has a first frequency distinctive of, or different or separate from, the base frequency. In some embodiments, applying the value to clock signal 103 may entail multiplying the base frequency of clock signal 103 by a value based on selection value 112 such that clock signal 117 has a first frequency different from the first frequency. Regardless, clock dividing circuit 115 may be configured to manipulate the frequency of clock signal 103 to produce clock signal 117, which, when used by ADC 120, may cause ADC 120 to perform operations at a sampling rate. Other methods of altering the frequency of clock signal 103 to produce clock signal 117 may be contemplated.

ADC 120 may be representative of one or more devices capable of performing the sampling and conversion operations on analog signals 104 based on clock signal 117 to produce digital values 118. In sequence diagram 300, ADC 120 may be coupled to receive a first analog signal and may be configured to convert the first analog signal at a sampling rate based on clock signal 117. As ADC 120 generates digital values 118 from the first analog signal, ADC 120 can provide the digital values 118 downstream to other systems, subsystems, or devices (e.g., a CPU, a direct memory access (DMA) controller, one or more peripherals) and to control circuit 105.

In some embodiments, in addition to receiving trigger 101, control circuit 105 may be configured to adjust the frequency of clock signal 117 based on analog signals 104. For example, in some embodiments, in response to receiving digital values 118 (that are generated based on analog-to-digital conversion of analog signals 104), control circuit 105 may be configured to control the value of selection signal 107 based on various parameters or factors, such as a first threshold value and a duration value. The first threshold value may correspond to a difference value between two different digital values. The duration value may correspond to a length of time during which clock signal 117 has a particular frequency.

Referring first to the first threshold value, control circuit 105 may be configured to determine that a change in the first set of digital values satisfies the first threshold value. More specifically, control circuit 105 may be configured to determine the change in the first set of digital values 118 based on a difference between two digital values (e.g., consecutive digital values) of the first set of digital values 118 produced by ADC 120. Control circuit 105 may include a comparator circuit to determine that the change in the digital values 118 satisfies the first threshold value. In particular, the comparator circuit may be configured to compare the difference between the two digital values and the first threshold value to determine that the difference satisfies the first threshold value. Based on such a determination, control circuit 105, or the comparator circuit thereof, may be configured to update the value for selection signal 107 and provide selection signal 107 to selector circuit 110, such that selector circuit 110 outputs selection value 112 having a value that causes clock dividing circuit 115 to generate clock signal 117 with a second frequency that is distinctive of the first frequency.

Referring next to the duration value, control circuit 105 may also be configured to monitor and/or control the lengths of duration that clock signal 117 has a particular frequency. To do so, control circuit 105 may include a counter circuit that is configured to generate a counter value representing the length of a duration in which clock signal 117 has a frequency. Following an example in which clock signal 117 includes a signal with a first frequency, the counter circuit may be configured to compare the counter value to a duration value to determine whether the length of duration in which clock signal 117 has the first frequency exceeds a duration value. Based on determining that the length of duration exceeds the duration value, control circuit 105, or the comparator circuit thereof, may be configured to update the value for selection signal 107 and provide selection signal 107 to selector circuit 110, such that selector circuit 110 outputs selection value 112 having a value that causes clock dividing circuit 115 to generate clock signal 117 with another frequency that is distinctive of the first frequency.

In some embodiments, the counter circuit may be configured to initiate the counter value in response to receiving the signal from the comparator circuit that indicates that the change in the first set of digital values satisfies the first threshold value. In other words, following the previous example, the counter circuit may be configured to initiate the counter value after ADC 120 produces the first set of digital values using clock signal 117 at one frequency and prior to ADC 120 producing a second set of digital values using clock signal 117 at a different frequency, which may be changed based on the change in the first set of digital values satisfying the threshold value. As illustrated in sequence diagram 300, the counter circuit may be configured to initiate the counter value after clock dividing circuit 115 generates the clock signal at the second frequency and ADC 120 begins to generate a second set of digital values 118 corresponding to the analog input. In some embodiments, the counter circuit may instead, or in addition, be configured to initiate the counter value in response to receiving a start signal from another system or circuit (e.g., the CPU, a peripheral).

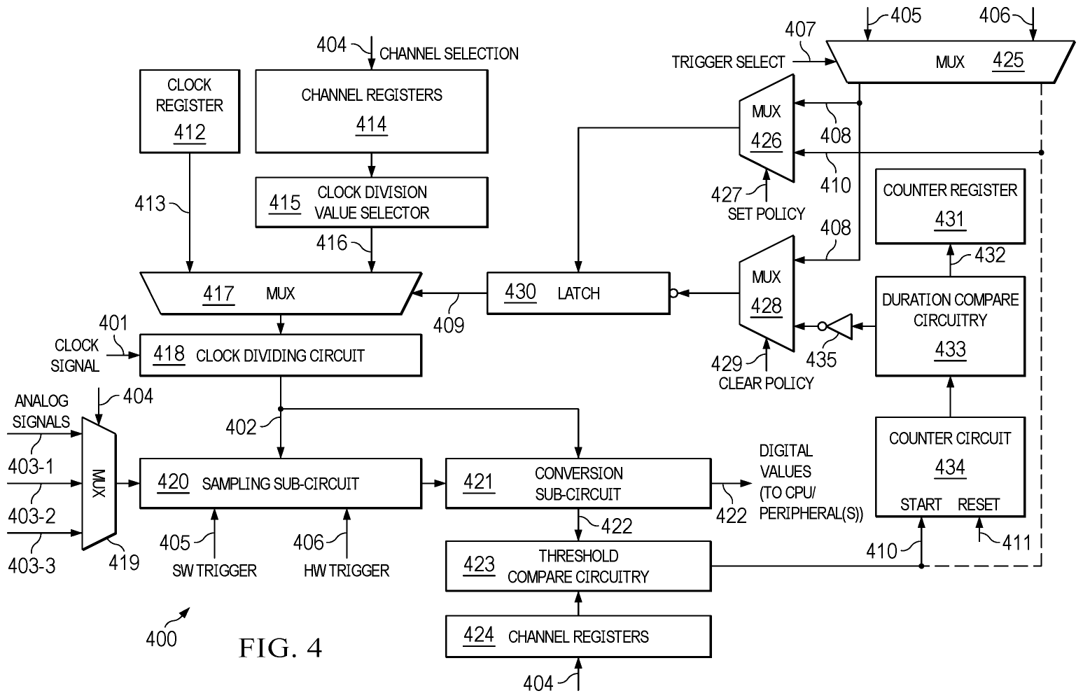

FIG. 4 illustrates an example system configurable to perform adaptive clock frequency processes in an implementation. FIG. 4 shows system 400, which includes clock register 412, channel registers 414, clock division value selector 415, multiplexer 417, clock dividing circuit 418, sampling sub-circuit 420, conversion sub-circuit 421, threshold compare circuitry 423, channel registers 424, multiplexer 425, multiplexer 426, set policy 427, multiplexer 428, clear policy 429, latch 430, counter register 431, duration compare circuitry 433, counter circuit 434, and logic gate 435. In various examples, elements system 400 may be configured to perform sampling and conversion operations and clock frequency transitioning techniques during the sampling and conversion operations, such as in operations 200 of FIG. 2.

In various embodiments, system 400 may be representative of a digital signal processing system capable of receiving analog signals 403, converting analog signals 403 at a desired sampling rate, and producing digital values 422 from analog signals 403 based on parameters and inputs, such as channel selection 404. Elements of system 400 may include dedicated, fixed-purpose hardware components capable of performing sampling and conversion operations and clock frequency management operations, such as operations 200 of FIG. 2. System 400 may be embodied in circuitry utilized in an embedded system or system-on-chip (SoC), such as a microcontroller unit (MCU). In an example, system 400 may include fewer, additional, or different elements that produce inputs to elements of system 400 or that receive outputs from system 400 (e.g., a central processing unit (CPU), one or more peripherals, a clock generation circuit).

System 400 may include control circuitry (e.g., control circuit 105) configured to receive various triggers and inputs and control operations of other elements of system 400 like clock dividing circuit 418, sampling sub-circuit 420, and conversion sub-circuit 421, among other elements, based on the triggers and inputs. For example, the control circuitry may include multiplexer 425, multiplexer 426, multiplexer 428, latch 430, logic gate 435, threshold compare circuitry 423, duration compare circuitry 433, and counter circuit 434.

Multiplexer 425 may be configured to receive software trigger 405, hardware trigger 406, and trigger select 407. Software trigger 405 and hardware trigger 406 may include values provided during the execution of software and during the operation of hardware devices, respectfully, that trigger a sampling and conversion operation of ADC circuitry of system 400. Software trigger 405 may be provided by a CPU, for example, while hardware trigger 406 may be provided by one or more peripherals (e.g., sensors). Trigger select 407 includes a value indicative of one of software trigger 405 or hardware trigger 406, such that multiplexer 425 outputs sampling trigger 408 corresponding to one of the triggers to multiplexers 426 and 428.

Multiplexer 426 may be coupled to receive sampling trigger 408 from multiplexer 425 and sampling trigger 410 from threshold compare circuitry 423. Each sampling trigger may correspond to different sampling rates with which to perform the sampling and conversion operations. In various embodiments, sampling trigger 408 may be indicative of a base sampling rate while sampling trigger 410 may be indicative of oversampling or an increased sampling rate. Multiplexer 426 may also receive set policy 427, which may indicate one of sampling triggers 408 or 410 to output at a given time to latch 430.

Similarly, multiplexer 428 may be coupled to receive sampling trigger 408 from multiplexer 425 and a sampling trigger from duration compare circuitry 433 via logic gate 435. Multiplexer 428 may also receive clear policy 429, which may correspond to a value that may clear latch 430 of a value associated with sampling triggers 408 or 410 from multiplexer 426.

Latch 430 may be representative of one or more latches or flip-flop circuits capable of storing a logical value based on the values provided by multiplexers 426 and 428. Latch 430 may be configured to store a value corresponding to one of sampling triggers 408 or 410 unless and until the value provided by multiplexer 428 clears latch 430. In either case, latch 430 may output selection signal 409 to selector circuitry of system 400 (e.g., selector circuit 110), or more particularly, to multiplexer 417.

Selector circuitry of system 400 may include one or more components configured to receive inputs related to clock frequencies and select a clock frequency value to provide to clock dividing circuitry 418 of system 400. For example, selector circuitry may include multiplexer 417 and clock division value selector 415.

Clock division value selector 415 may include one or more components configured to receive clock division values from channel registers 414, select clock division value 416 based on channel selection 404, and output clock division value 416 to multiplexer 417. Channel registers 414 may include one or more register locations that store clock division values corresponding to each of a plurality of analog channels. Each analog channel may correspond to a peripheral that produces one specific analog signal 403. An analog channel may be indicated via channel selection 404, which may correspond to software trigger 405 and/or hardware trigger 406. For example, as shown in FIG. 4, system 400 may be configured to perform sampling and conversion operations on three analog signals 403-1, 403-2, and 403-3, where 403-1, 403-2, and 403-3 may represent different types of analog signals (e.g., pressure, speed, and temperature). As described above, in some embodiments, system 400 may sample and convert analog signals 403-1, 403-2, and 403-3 sequentially or in parallel. Regardless, channel selection 404 may be configured as a 2-bit binary value to indicate the different channels. For example, a value “01” of channel selection 404 may indicate channel-1 corresponding to analog signal 403-1 (such that 403-1 is the analog signal that is being (or to be) sampled and converted by system 400), a value “10” may indicate channel-2 corresponding to analog signal 403-2 (such that 403-2 is the analog signal that is being (or to be) sampled and converted), and a value “11” may indicate channel-3 corresponding to analog signal 403-3 (such that 403-3 is the analog signal that is being (or to be) sampled and converted). Additionally, hardware trigger 405 and/or software trigger 406 may correspond to different analog signals 403 or channels. For example, hardware trigger 405 may correspond to analog signal 403-2 or channel-2, software trigger 406 may correspond to analog signal 403-3 or channel-3, and no trigger signal corresponds to analog signal 403-1 or channel-1. Thus, when system 400 receives hardware trigger 405, it may increase the frequency of clock signal 402 that is used for sampling and conversion operations of analog signal 403-2. Similarly, when system 400 receives software trigger 406, it may increase the frequency of clock signal 402 that is used for sampling and conversion operations of analog signal 403-3.

Multiplexer 417 may also be coupled to receive a clock frequency value 413 from clock register 412. Clock register 412 may include one or more register locations that store values indicative of a clock frequency. In some embodiments, clock frequency value 413 may correspond to a base frequency. Based on selection signal 409, multiplexer 417 may be configured to select either clock frequency value 413 or clock division value 416 and provide a selection value indicative thereof to clock dividing circuit 418.

Clock dividing circuit 418 may be representative of one or more devices configured to receive the selection value from multiplexer 417, receive a clock signal 401, and apply the selection value to clock signal 401 to produce clock signal 402 for use by ADC circuitry of system 400. In various embodiments, clock signal 402 includes a signal with a base frequency. Clock dividing circuit 418 may be configured to increase the frequency of clock signal 401, decrease the frequency of clock signal 401, or retain the frequency of clock signal 401 based on the selection value. For example, if multiplexer 417 provides clock frequency value 413 to clock dividing circuit 418, clock dividing circuit 418 may retain the frequency of clock signal 401 such that clock signal 402 includes a signal with the base frequency. In particular, clock frequency value 413 may include a value of 1, such that applying the value to the frequency of clock signal 401 does not increase nor decrease the frequency of clock signal 402. By way of another example, if multiplexer 417 provides clock division value 416 to clock dividing circuit 418, clock dividing circuit 418 may apply the value of clock division value 416 to the frequency of clock signal 401, which may increase or decrease the value of the frequency of clock signal 402.

ADC circuitry of system 400 (e.g., ADC 120) may receive clock signal 402 and perform sampling and conversion operations on one or more of analog signals 403 at a sampling rate based on the frequency of clock signal 402 to produce digital values 422. The ADC circuitry may include multiplexer 419, sampling sub-circuit 420, and conversion sub-circuit 421. Multiplexer 419 may be configured to receive analog signals 403 from one or more peripherals and channel selection 404. Each of analog signals 403-1, 403-2, and 403-3 may correspond to a different peripheral. For example, analog signal 403-1 may include analog signals from a first sensor, analog signals 403-2 may include analog signals from a second sensor, and analog signals 403-3 may include analog signals from a third sensor. Channel selection 404 may indicate one of the analog signals, which may cause multiplexer 419 to provide an identified set of analog signals to sampling sub-circuit 420.

Sampling sub-circuit 420 may include one or more devices, such as a capacitive digital-to-analog converter (CDAC) and a comparator, among other elements, configured to perform sampling operations on analog signals 403 based on software trigger 405 and/or hardware trigger 406. Sampling sub-circuit 420 may operate at a speed, or with a sampling rate, based on the frequency of clock signal 402. Sampling sub-circuit 420 may provide sampled values to conversion sub-circuit 421.

Conversion sub-circuit 421 may include one or more devices, such as an ADC, configured to perform conversion operations on sampled values at a sampling rate based on the frequency of clock signal 402. Conversion sub-circuit 421 can produce digital values 422 and provide digital values 422 downstream to one or more systems, subsystems, or devices, such as a CPU and/or one or more peripherals, and to threshold compare circuitry 423 of the control circuitry of system 400.

Threshold compare circuitry 423 may be configured to determine that a change in a first set of digital values 422 satisfies a first threshold value. More specifically, threshold compare circuitry 423 may determine the change in the first set of digital values 422 based on a difference between two digital values (e.g., between two or more consecutive digital values) of the first set of digital values 422 produced by sampling sub-circuit 420 and conversion sub-circuit 421. In some examples, the delta value may be based on a first derivative, a second derivative of the digital values. For example, threshold compare circuitry may be configured to filter the digital values (e.g., with a moving/running average filter) and generate the delta value based on a difference between two filtered values. Additionally, or alternatively, threshold compare circuitry 423 may be configurable to implement a debouncing technique to avoid outputting sampling trigger 410 based on a single delta value. To implement the debouncing technique, threshold compare circuitry 423 could calculate the delta value based on digital values that are not consecutive. The first threshold value may correspond to a delta value between the two digital values and may be obtained from channel registers 424. Channel registers 424 may include one or more register locations that store threshold values corresponding to an analog channel, which can be identified by channel selection 404.

In various embodiments, threshold compare circuitry 423 may include a comparator circuit to determine that the change in the digital values 422 satisfies the first threshold value. In particular, the comparator circuit may be configured to compare the difference between the two digital values and the first threshold value to determine that the difference satisfies the first threshold value. Based on such a determination, threshold compare circuitry 423 may be configured to output sampling trigger 410 and provide sampling trigger 410 to the selection circuitry of system 400, or more particularly, to multiplexer 426 and counter circuit 434.

In response to receiving sampling trigger 410, multiplexer 426 may be configured to output a value corresponding to sampling trigger 410 to latch 430. Latch 430 may store the value of sampling trigger 410, update the value of selection signal 409 accordingly, and provide selection signal 409 to multiplexer 417. In various embodiments, multiplexer 417 may be configured to select clock frequency value 413 based on selection signal 409 including a value based on sampling trigger 408. In other words, sampling trigger 408 may enable sampling and conversion operations at a base sampling rate. However, in some embodiments, sampling trigger 408 may enable sampling and conversion operations at an increased sampling rate relative to the base sampling rate. Multiplexer 417 may be configured to select clock division value 416 based on selection signal 409 including a value based on sampling trigger 410. In other words, sampling trigger 410 may enable sampling and conversion operations at an increased sampling rate relative to the base sampling rate. Additional example details of increased sampling rates can be found in commonly assigned U.S. Pat. No. 10,491,234, entitled “Configurable Oversampling for an Analog-to-Digital Converter,” granted on Nov. 26, 2019, which is incorporated by reference in its entirety.

During a first example sampling and conversion sequence, selection signal 409 may include a value corresponding to sampling trigger 408 such that sampling sub-circuit 420 and conversion sub-circuit 421 perform respective operations at the base sampling rate to produce a first set of digital values 422. Based on determining that a change in digital values 422 satisfies the first threshold value, threshold compare circuitry 423 can output sampling trigger 410 to enable a second example sampling and conversion sequence. In this second example, multiplexer 417 updates selection signal 409 with a value corresponding to sampling trigger 410 which may cause clock dividing circuit 418 to change the frequency of clock signal 402 to a different frequency based on applying clock division value 416 to the frequency. In this way, clock signal 402 may include a higher frequency relative to the base frequency, which may cause sampling sub-circuit 420 and conversion sub-circuit 421 to perform respective operations at a higher sampling rate to produce a second set of digital values 422.

Additionally, threshold compare circuitry 423 provides sampling trigger 410 to counter circuit 434 to enable a counter sequence corresponding to the second example sampling and conversion sequence. Counter circuit 434 may include one or more circuits capable of initiating and maintaining a counter value representing a length of duration that clock signal 402 has a particular frequency. The counter value may be initiated based on receiving sampling trigger 410 and may be reset to an initial value based on receiving a reset signal 411.

Duration compare circuitry 433 may be coupled to counter circuit 434 to obtain the counter value and to counter register 431 to obtain duration threshold 432. Counter register 431 may include one or more register locations at which threshold values corresponding to lengths of duration in which clock signal 402 has a particular frequency may be stored. For example, counter register 431 may include threshold values corresponding to each analog channel, or to each clock division value associated with a channel (e.g., clock division value 416), including duration threshold 432.

Duration compare circuitry 433 may include one or more devices configured to monitor the lengths of duration that clock signal 402 has a particular frequency. Duration compare circuitry 433 can identify the counter value of counter circuit 434 and perform a comparison between the counter value and duration threshold 432. Duration compare circuitry 433 can output a signal having a value based on a result of the comparison. If the counter value has not exceeded duration threshold 432, duration compare circuitry 433 may output a signal having a first value to logic gate 435, a NOT gate. Logic gate 435 can invert the value and provide the inverted value to multiplexer 428. In this case, multiplexer 428 outputs a value to latch 430 that might not clear the latch 430, based on clear policy 429, and thus, latch 430 may continue outputting selection signal 409 with a value corresponding to sampling trigger 410. However, if the counter value has exceeded duration threshold 432, duration compare circuitry 433 may output a signal having a second value, which may cause multiplexer 428 to output a value to latch 430 that clears latch 430 and causes latch 430 to output selection signal 409 with a value corresponding to sampling trigger 408. Thus, when the counter value exceeds duration threshold 432, clock dividing circuit 418 may produce clock signal 402 with the base frequency, such that sampling sub-circuit 420 and conversion sub-circuit 421 perform respective operations at the base sampling rate.

For each iteration of sampling and conversion via the ADC circuitry of system 400, the control circuitry elements may be configured to compare changes in values of digital values 422 against threshold values to determine whether to increase or decrease the frequency of clock signal 402 via the selector circuitry elements and clock dividing circuit 418. For each iteration of sampling and conversion via the ADC circuitry in which clock signal 402 includes a signal with a frequency higher than the base frequency, the control circuitry elements may be configured to initiate the counter value via counter circuit 434 to determine whether to decrease the frequency of clock signal 402 via the selector circuitry elements and clock dividing circuit 418.

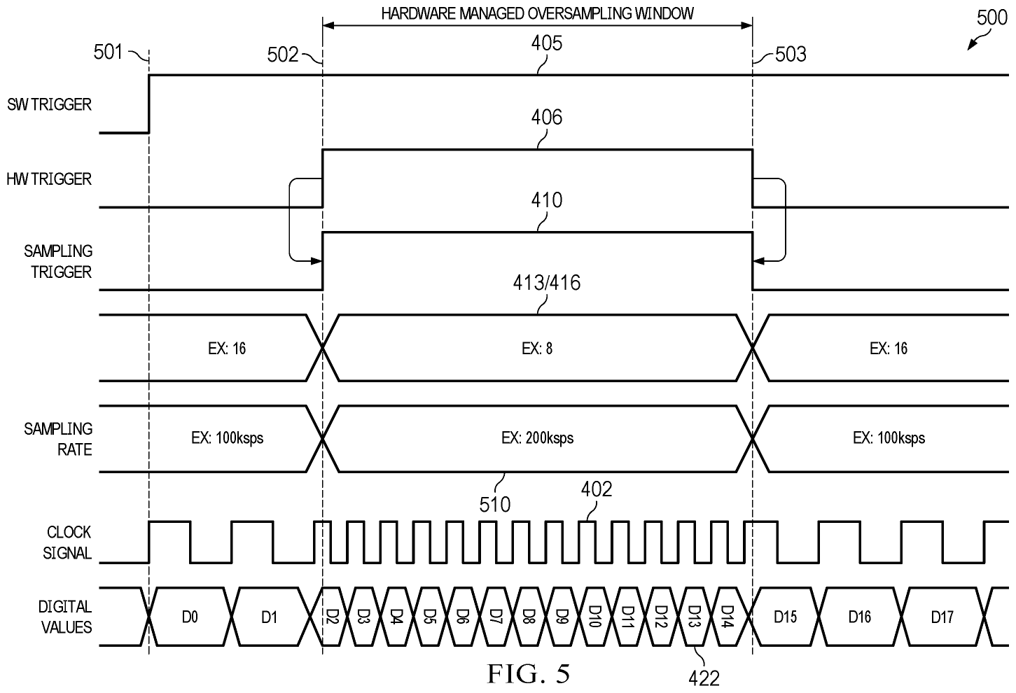

FIG. 5 illustrates an example timing diagram corresponding to dynamically transitioning the frequency of a clock signal during operation of an analog-to-digital converter in an implementation. FIG. 5 shows timing diagram 500, which references elements of system 400 of FIG. 4 and logical states thereof during times 501, 502, and 503. The logical state values demonstrated by timing diagram 500 may be illustrated as high logical signals (“1” or “on”) or low logical signals (“0” or “off”).

Time 501 represents a first time during which components of system 400 may begin to perform sampling and conversion operations to convert analog signals 403 to sets of digital values 422 based on software trigger 405 transitioning from a low logical state to a high logical state. In this way, software trigger 405 may enable sampling and conversion operations 403 at a base sampling rate to begin. At this time, hardware trigger 406 is in the low logical state, and thus, sampling trigger 410 is also in the low logical state. Accordingly, multiplexer 425 may provide sampling trigger 408 to multiplexers 426 and 428 based on receiving software trigger 405, which may cause latch 430 to output selection signal 409 with a value corresponding to sampling trigger 408 to multiplexer 417. Multiplexer 417 may select clock frequency value 413 (e.g., 16) based on selection signal 409, which may correspond to a base frequency or base sampling rate 510. Based on clock frequency value 413, clock dividing circuit 418 can produce clock signal 402 with the base frequency and provide clock signal 402 to sampling sub-circuit 420 and conversion sub-circuit 421. Sampling sub-circuit 420 and conversion sub-circuit 421 can operate at sampling rate 510 (e.g., 100 kilosamples per second (ksps)) based on clock signal 402 and begin to produce a first set of digital values 422 at time 501.

The above operations may continue from time 501 to time 502. At time 502, while software trigger 405 remains in the high logical state, hardware trigger 406 may transition from the low logical state to the high logical state, which may initiate sampling and conversion operations at an increased or oversampling rate. Thus, sampling trigger 410 may also transition from the low logical state to the high logical state. When hardware trigger 406 is provided to elements of system 400 (e.g., multiplexer 425), multiplexer 425 may output sampling trigger 410 to multiplexer 426, which may cause latch 430 to output selection signal 409 with a value corresponding to sampling trigger 410 to multiplexer 417. Multiplexer 417 may select clock division value 416 (e.g., 8) based on selection signal 409, which may correspond to a frequency higher than the base frequency. Based on clock division value 416, clock dividing circuit 418 can increase the frequency of clock signal 402 and provide clock signal 402 to sampling sub-circuit 420 and conversion sub-circuit 421. Sampling sub-circuit 420 and conversion sub-circuit 421 can operate at an increased sampling rate 510 (e.g., 200 ksps) based on clock signal 402 and produce a second set of digital values 422 from time 502 to time 503.

At time 503, software trigger 405 remains in the high logical state, but hardware trigger 406 transitions from the high logical state to the low logical state, which causes sampling trigger 410 to transition from the high logical state to the low logical state. It follows that the frequency of clock signal 402, and thus sampling rate 510, may be decreased back to respective base rates based on hardware trigger 406 and sampling trigger 410 having low logical values. Sampling sub-circuit 420 and conversion sub-circuit 421 can once again operate at the base sampling rate 510 (e.g., 100 ksps) and produce a third set of digital values 422 at time 503.

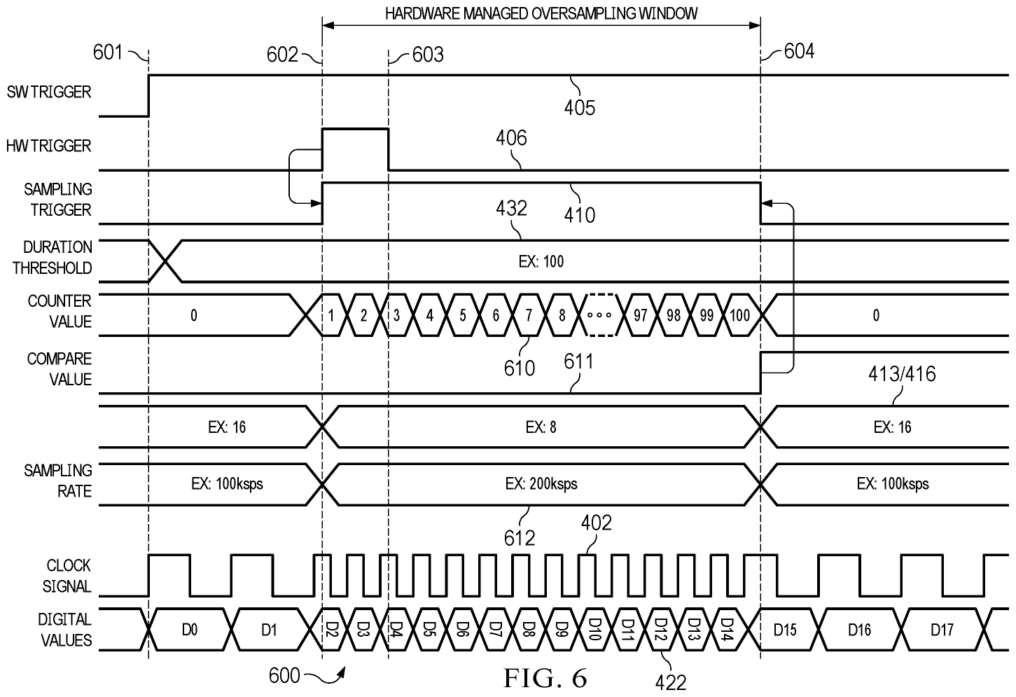

FIG. 6 illustrates an example timing diagram corresponding to dynamically transitioning the frequency of a clock signal during operation of an analog-to-digital converter in an implementation. FIG. 6 shows timing diagram 600, which references elements of FIG. 4 and logical states thereof during times 601, 602, 603, and 604. The logical state values demonstrated by timing diagram 600 may be illustrated as high logical signals (“1” or “on”) or low logical signals (“0” or “off”).

Time 601 represents a first time during which components of system 400 may begin to perform sampling and conversion operations to convert analog signals 403 to sets of digital values 422 based on software trigger 405 transitioning from a low logical state to a high logical state. At this time, hardware trigger 406 is in the low logical state, so system 400 may perform sampling and conversion operations at the base sampling rate. Thus, sampling trigger 410 is also in the low logical state. Accordingly, multiplexer 425 may provide sampling trigger 408 to multiplexers 426 and 428 based on receiving software trigger 405, which may cause latch 430 to output selection signal 409 with a value corresponding to sampling trigger 408 to multiplexer 417. Multiplexer 417 may select clock frequency value 413 (e.g., 16) based on selection signal 409, which may correspond to a base frequency or base sampling rate 612. Based on clock frequency value 413, clock dividing circuit 418 can produce clock signal 402 with the base frequency and provide clock signal 402 to sampling sub-circuit 420 and conversion sub-circuit 421. Sampling sub-circuit 420 and conversion sub-circuit 421 can operate at sampling rate 612 (e.g., 100 ksps) based on clock signal 402 and begin to produce a first set of digital values 422 at time 601.

Between time 601 and 602, counter circuit 434 and duration compare circuitry 433 might not be enabled as sampling trigger 410 remains in the low logical state. However, at time 602, while software trigger 405 remains in the high logical state, hardware trigger 406 may transition from the low logical state to the high logical state, and thus, sampling trigger 410 may also transition from the low logical state to the high logical state. When hardware trigger 406 is provided to elements of system 400 (e.g., multiplexer 425), multiplexer 425 may output sampling trigger 410 to multiplexer 426, which may cause latch 430 to output selection signal 409 with a value corresponding to sampling trigger 410 to multiplexer 417. Multiplexer 417 may select clock division value 416 (e.g., 8) based on selection signal 409, which may correspond to a frequency higher than the base frequency. Based on clock division value 416, clock dividing circuit 418 can increase the frequency of clock signal 402 and provide clock signal 402 to sampling sub-circuit 420 and conversion sub-circuit 421. Sampling sub-circuit 420 and conversion sub-circuit 421 can operate at an increased sampling rate 612 (e.g., 200 ksps) based on clock signal 402 and produce a second set of digital values 422 at time 602.

At time 602, counter circuit 434 may be enabled in response to receiving sampling trigger 410 that has a high logical value. Counter circuit 434 may initiate counter value 610. Counter value 610 may begin with a value of 0, and counter circuit 434 can increment counter value 610 by 1 each time one of digital values 422 is produced by conversion sub-circuit 421. Duration compare circuitry 433 may be configured to identify duration threshold 432 that corresponds to hardware trigger 406 from counter register 431. In this example, duration threshold 432 may include a value of 100.

At time 603, hardware trigger 406 transitions from the high logical state to the low logical state. However, because counter circuit 434 and duration compare circuitry 433 have been enabled, and duration threshold 432 has not been exceeded, sampling trigger 410 may remain in the high logical state. Accordingly, sampling sub-circuit 420 and conversion sub-circuit 421 may continue to produce digital values 422 at the increased sampling rate 612.

At time 604, duration compare circuitry 433 may determine that counter value 610 of counter circuit 434 meets or exceeds duration threshold 432. In response to determining that counter value 610 meets or exceeds duration threshold 432, duration compare circuitry 433 can output compare value 611, including a high logical value, to logic gate 435. This may cause multiplexer 428 to provide a value to latch 430 that clears the previously stored value of selection signal 409 (i.e., sampling trigger 410) of latch 430. Thus, latch 430 may update the value of selection signal 409 to correspond to the value of sampling trigger 408, which may cause clock dividing circuit 418 to decrease the frequency of clock signal 402 to the base frequency. Using clock signal 402 at the base frequency, sampling sub-circuit 420 and conversion sub-circuit 421 can operate at the base sampling rate 612 to produce a third set of digital values 422.

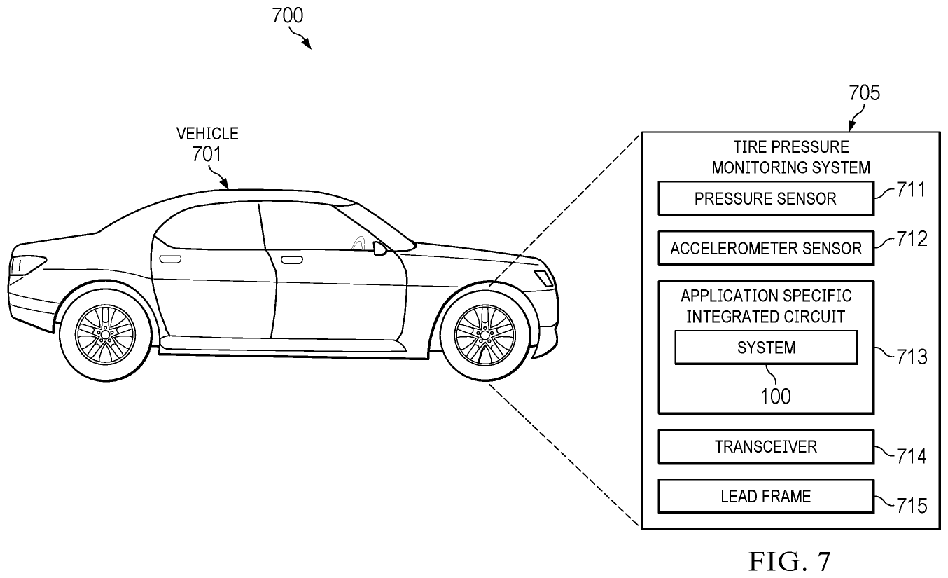

FIG. 7 illustrates an example system configurable to perform adaptive clock frequency processes in an implementation. FIG. 7 shows system 700, which includes vehicle 701 and tire pressure monitoring system 705 thereof. Tire pressure monitoring system 705 includes pressure sensor 711, accelerometer sensor 712, application specific integrated circuit (ASIC) 713, transceiver 714, and lead frame 715. Although FIG. 7 shows vehicle 701 in system 700, the techniques of this disclosure may be implemented in other non-vehicular systems, such as industrial systems, medical systems, building systems, edge computing devices, IoT devices, and/or wearable devices.

Vehicle 701 may be representative of a car, truck, or other motor vehicle having tires and associated sensors and components. In some embodiments, each tire may include various elements that form a tire pressure monitoring system, such as tire pressure monitoring system 705. Tire pressure monitoring system 705 may be configured to sense and monitor pressure and motion values within a tire of vehicle 701, convert analog signals corresponding to the values to digital signals, and provide information about the values to other components of vehicle 701, such as an on-board computing system, peripherals, and the like.

In system 700, tire pressure monitoring system 705 may include pressure sensor 711 and accelerator sensor 712 to collect analog data. Pressure sensor 711 may be configured to sense pressure within a given tire (e.g., a value of pounds per square inch (PSI)). Accelerometer sensor 712 may be configured to sense motion of the tire, such as a rotation of the tire when vehicle 701 drives forwards or backwards. Both pressure sensor 711 and accelerometer sensor 712 may produce analog signals with respective data and may be coupled to provide the analog signals to ASIC 713.

ASIC 713 may be representative of a processing system or device configured to receive the analog signals, convert the analog signals to digital signals, and provide the digital signals downstream to other components internal and external to vehicle 701 via transceiver 714. Other types of processing devices may be used in addition to or instead of ASIC 713, such as a central processing unit (CPU), a general purpose processor, a field-programmable gate array (FPGA), a digital signal processor (DSP), or the like.

ASIC 713 may include system 100 to perform sampling and conversion operations on the analog signals from pressure sensor 711 and accelerometer sensor 712. In various embodiments, ASIC 713 may provide an input (e.g., trigger 101, software trigger 405) to elements of system 100 to begin the sampling and conversion operations. Additionally, or instead, pressure sensor 711 and accelerometer sensor 712 may provide inputs (e.g., trigger 101, hardware trigger 406) to elements of system 100 to begin the sampling and conversion operations.

The elements of system 100 may be configured to perform the sampling and conversion operations at a sampling rate based on which input is received and at what point in time the input is received. For example, if accelerometer sensor 712 does not detect motion of vehicle 701, or in other words, vehicle 701 is stationary/parked, ASIC 713 may be configured to perform sampling and conversion operations of analog signals at a base frequency rate. However, if accelerometer sensor 712 detects motion of vehicle 701, ASIC 713 may be configured to perform sampling and conversion operations of analog signals at an increased sampling rate (e.g., oversampling rate) relative to the base sampling rate to identify pressure and/or motion values more quickly. Upon producing digital values of the pressure and/or motion data, ASIC 713 can provide the digital values downstream using transceiver 714.

Lead frame 715 may be representative of a die pad on which ASIC 713 and other elements of tire pressure monitoring system 705 may be affixed. In some embodiments, lead frame 715 may be made of a metal or a conductive material and include one or more conductive features that may be used to couple elements to each other (e.g., conductive traces). It follows that tire pressure monitoring system 705 may be a system-on-chip (SoC) or include elements coupled together on a board (e.g., a printed circuit board).

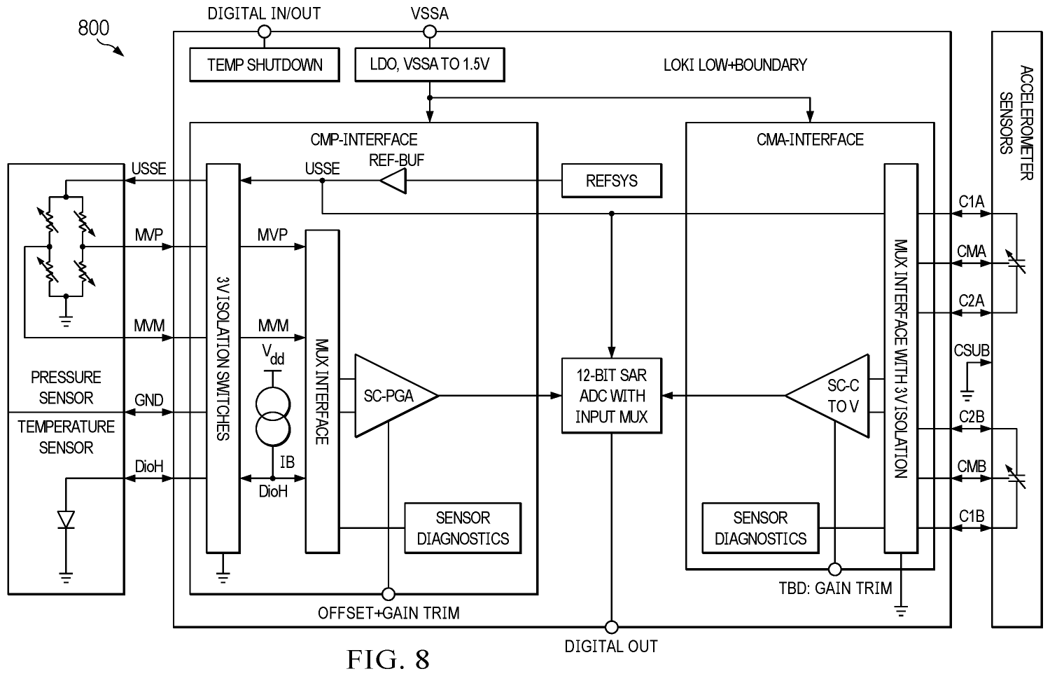

FIG. 8 illustrates an example circuit configurable to perform adaptive clock frequency processes in an implementation. FIG. 8 shows circuit 800, which includes elements of a tire pressure monitoring system, such as tire pressure monitoring system 705 of FIG. 7.

In various embodiments, circuit 800 may be representative of a tire pressure monitoring system configured to obtain analog measurements of pressure and motion, among other information, via sensors (e.g., accelerometer sensors, pressure sensors, temperature sensors) and convert the analog measurements to digital measurements for use by other systems, subsystems, circuits, and the like. To do so, circuit 800 includes various elements, such as a 12-bit SAR ADC (e.g., ADC 120), one or more multiplexers, multiplexer interfaces, isolation switches, buffers, amplifiers, power converters, power management units, and one or more sensors, such as accelerometer sensors, pressure sensors, and temperature sensors, and other elements of a sampling and conversion system, such as control circuitry (e.g., control circuitry 105), selector circuitry (e.g., selector circuit 110), and clock dividing circuitry (e.g., clock dividing circuitry 115).

In operation, sensors of circuit 800 may be configured to obtain analog measurements of a system (e.g., vehicle 701) and provide the analog measurements to the SAR ADC. The sensors may also provide triggers (e.g., trigger 101, hardware trigger 406) to control circuitry of circuit 800 to enable sampling and conversion operations to convert the analog measurements to digital measurements. The control circuitry may identify the triggers and corresponding analog measurements and provide a selection signal to selector circuitry. The selector circuitry can select a clock frequency value based on the selection signal to cause the clock dividing circuitry to generate a clock signal with a frequency based on the clock frequency value. The SAR ADC can use the clock signal to operate at a sampling rate based on the frequency of the clock signal and convert the selected analog measurements to digital measurements for use downstream. This process may iterate throughout operation of circuit 800. As such, the SAR ADC can perform conversion operations at varied sampling rates based on factors, such as the triggers, the lengths of duration in which the SAR ADC operates at a given sampling rate, and the number of digital measurements the SAR ADC produces.

While circuit 800 is discussed with respect to a tire pressure monitoring system and with respect to a vehicle, circuit 800 may be utilized in other environments and systems, such as in cloud applications, fusion applications, industrial devices and applications, wearable devices, and more, that would benefit from gathering additional digital measurements under specific conditions (e.g., triggers).

While some examples provided herein are described in the context of a digital signal processing system, sampling and conversion circuitry, clock circuitry, control circuitry, selector circuitry, tire pressure monitoring circuitry, an embedded system or system-on-chip, sub-circuit, system, subsystem, component, device, architecture, or environment, it should be understood that the elements, components, systems, and methods described herein are not limited to such embodiments and may apply to a variety of other processes, systems, applications, devices, and the like, such as other circuits, logic devices, transistors, and the like, in the context of sampling and conversion functionality, for example. Accordingly, aspects of the present invention may be embodied as other systems, methods, and other configurable systems.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The phrases “in some embodiments,” “according to some embodiments,” “in the embodiments shown,” “in other embodiments,” and the like generally mean the particular feature, structure, or characteristic following the phrase is included in at least one implementation of the present technology, and may be included in more than one implementation. In addition, such phrases do not necessarily refer to the same embodiments or different embodiments.

The above Detailed Description of examples of the technology is not intended to be exhaustive or to limit the technology to the precise form disclosed above. While specific examples for the technology are described above for illustrative purposes, various equivalent modifications are possible within the scope of the technology, as those skilled in the relevant art will recognize. For example, while processes or blocks are presented in a given order, alternative implementations may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed or implemented in parallel or may be performed at different times. Further any specific numbers noted herein are only examples: alternative implementations may employ differing values or ranges.

The teachings of the technology provided herein can be applied to other systems, not necessarily the system described above. The elements and acts of the various examples described above can be combined to provide further implementations of the technology. Some alternative implementations of the technology may include not only additional elements to those implementations noted above, but also may include fewer elements.

These and other changes can be made to the technology in light of the above Detailed Description. While the above description describes certain examples of the technology, and describes the best mode contemplated, no matter how detailed the above appears in text, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the above Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. For example, while only one aspect of the technology is recited as a computer-readable medium claim, other aspects may likewise be embodied as a computer-readable medium claim, or in other forms, such as being embodied in a means-plus-function claim. Any claims intended to be treated under 35 U.S.C. § 112(f) will begin with the words “means for” but use of the term “for” in any other context is not intended to invoke treatment under 35 U.S.C. § 112(f). Accordingly, the applicant reserves the right to pursue additional claims after filing this application to pursue such additional claim forms, in either this application or in a continuing application.

What is claimed is:

1. A device, comprising:
an analog-to-digital converter (ADC) configured to:
receive a first analog signal;
receive a first clock signal; and
generate a first set of digital values corresponding to the first analog signal based on the first clock signal; and
a control circuit coupled to the ADC and configured to:
determine that a change in the first set of digital values satisfies a first threshold value; and
increase the first clock signal from a first frequency to a second frequency in response to determining that the change in the first set of digital values satisfies the first threshold value.

2. The device of claim 1, further comprising:
a selector circuit configured to:
receive a first value corresponding to the first frequency of the first clock signal and a second value corresponding to the second frequency of the first clock signal; and
select one of the first value and the second value based on a selection signal to generate a selected value; and
a clock dividing circuit configured to:
receive a second clock signal; and
divide the second clock signal based on the selected value to generate the first clock signal for the ADC.

3. The device of claim 2, wherein the control circuit is configured to:
determine the change in the first set of digital values based on a difference between two digital values of the first set of digital values generated by the ADC; and
generate a value for the selection signal based on determining that the difference satisfies the first threshold value, such that the clock dividing circuit generates the first clock signal at the second frequency.

4. The device of claim 3, wherein the two digital values are consecutive values generated by the ADC.

5. The device of claim 3, wherein the control circuit comprises a comparator circuit configured to:
compare the difference between the two digital values and the first threshold value to determine that the difference satisfies the first threshold value.

6. The device of claim 2, wherein the control circuit is configured to:
determine that a length of duration in which the first frequency of the first clock signal is increased to the second frequency exceeds a duration value; and
generate another value for the selection signal based on determining that the length of duration exceeds the duration value, such that the clock dividing circuit generates the first clock signal at the first frequency.

7. The device of claim 6, wherein the control circuit comprises:
a counter circuit configured to generate a counter value representing the length of duration; and
a comparator circuit configured to generate the other value for the selection signal based on a comparison between the counter value and the duration value.

8. The device of claim 7, wherein the counter circuit is configured to:
receive a signal indicating that the change in the first set of digital values satisfies the first threshold value; and
initiate the counter value in response to receiving the signal.

9. The device of claim 2, wherein the control circuit is configured to:
receive a trigger signal; and
generate a value for the selection signal based on receiving the trigger signal, such that the clock dividing circuit generates the first clock signal at the second frequency.

10. The device of claim 1, wherein:
the ADC is configured to generate a second set of digital values corresponding to a second analog signal based on a second clock signal;
the control circuit is configured to increase the second clock signal from a third frequency to a fourth frequency based on determining that a change in the second set of digital values satisfies a second threshold value, and
the second frequency is distinctive of the fourth frequency, and the first threshold value is distinctive of the second threshold value.

11. A method, comprising:
receiving a first analog signal;
receiving a first clock signal;
generating a first set of digital values corresponding to the first analog signal based on the first clock signal;
determining that a change in the first set of digital values satisfies a first threshold value; and
increasing the first clock signal from a first frequency to a second frequency in response to determining that the change in the first set of digital values satisfies the first threshold value.

12. The method of claim 1, further comprising:
receiving a first value corresponding to the first frequency of the first clock signal and a second value corresponding to the second frequency of the first clock signal;
selecting one of the first value and the second value based on a selection signal to generate a selected value;
receiving a second clock signal; and
dividing the second clock signal based on the selected value to generate the first clock signal.

13. The method of claim 12, further comprising:
determining the change in the first set of digital values based on a difference between two digital values of the first set of digital values; and
generating a value for the selection signal based on determining that the difference satisfies the first threshold value;
wherein generating the first clock comprises generating the first clock signal at the second frequency; and
wherein determining that the difference satisfies the first threshold value comprises comparing the difference between the two digital values and the first threshold value.

14. The method of claim 12, further comprising:
determining that a length of duration in which the first frequency of the first clock signal is increased to the second frequency exceeds a duration value, wherein the length of duration is based on a counter value; and
generating another value based on determining that the length of duration exceeds the duration value based on a comparison between the counter value and the duration value;
wherein generating the first clock signal comprises generating the first clock signal at the first frequency.

15. The method of claim 14, further comprising:
receiving a signal indicating that the change in the first set of digital values satisfies the first threshold value; and
initiating the counter value in response to receiving the signal.

16. The method of claim 12, further comprising:
receiving a trigger signal; and
generating a value for the selection signal based on receiving the trigger signal;
wherein generating the first clock signal comprises generating the clock signal at the second frequency.

17. The method of claim 11, further comprising:
generating a second set of digital values corresponding to a second analog signal based on a second clock signal; and
increasing the second clock signal from a third frequency to a fourth frequency based on determining that a change in the second set of digital values satisfies a second threshold value;
wherein the second frequency is distinctive of the fourth frequency, and the first threshold value is distinctive of the second threshold value.

18. A system, comprising:
a sensor;
an analog-to-digital converter (ADC) coupled to the sensor and configured to:
receive a first analog signal from the sensor;
receive a first clock signal; and
generate a first set of digital values corresponding to the first analog signal based on the first clock signal; and
a control circuit coupled to the ADC and configured to:
determine that a change in the first set of digital values satisfies a first threshold value; and
increase the first clock signal from a first frequency to a second frequency in response to determining that the change in the first set of digital values satisfies the first threshold value.

19. The system of claim 18, further comprising:
a selector circuit configured to:
receive a first value corresponding to the first frequency of the first clock signal and a second value corresponding to the second frequency of the first clock signal; and
select one of the first value and the second value based on a selection signal to generate a selected value; and
a clock dividing circuit configured to:
receive a second clock signal; and
divide the second clock signal based on the selected value to generate the first clock signal for the ADC;
wherein the control circuit is further configured to:
determine the change in the first set of digital values based on a difference between two digital values of the first set of digital values generated by the ADC; and
generate a value for the selection signal based on determining that the difference satisfies the first threshold value, such that the clock dividing circuit generates the first clock signal at the second frequency.

20. The system of claim 18, wherein the sensor includes one or more of: a tire pressure sensor, an accelerometer sensor, a temperature sensor, and a voltage sensor.
